(19) United States
(12) Patent Application Publication
(10) Pub. No.: US 2020/0084850 A1
(43) Pub. Date: Mar. 12, 2020

(54) LIGHT GRID

(71) Applicant: SICK AG, Waldkirch (DE)

(72) Inventor: Johannes EBLE, Waldkirch (DE)

(73) Assignee: SICK AG

(21) Appl. No.: 16/538,971

(22) Filed: Aug. 13, 2019

(30) Foreign Application Priority Data
Sep. 7, 2018 (EP) 18193290.6

(51) Int. Cl. H05B 33/08; H01L 31/0232; H01L 27/15; H01L 27/146; H01L 31/14

(52) U.S. Cl. CPC H05B 33/0848; H01L 31/0232; H01L 31/143; H01L 27/14627; H01L 27/156

(57) ABSTRACT

The light grid according to the invention comprises several light emitting units for emitting light beams, several light receiving units which supply reception signals according to the incidence of light and which can receive the transmitted light beams to form the light grid in case the beam paths are free, receiving optics and an evaluation unit for evaluating the intensity of the incidence of light on the light receiving units. In order to increase the performance of the light grid by limiting the field of view of the light receivers, the receiving optics comprise a substrate having a microlens array and each microlens is associated with an aperture and the apertures are each at the focal point of the associated microlens.

The invention concerns a light grid with several light emitting units for the emission of light beams, several light receiving units which supply reception signals according to the incidence of light and which are able to receive the emitted light beams in case the beam paths are free to form the light grid, receiving optics and an evaluation unit for evaluating the intensity of the incidence of light on the light receiving units.

The performance of a light grid depends, among other things, on the field of view of the receiver, whereby the field of view is determined in particular by the reception angle. If a photodiode without additional optics is used on the receiving side, the reception angle is Ω=2π, i.e. light is received from a hemisphere without additional measures.

This results in disadvantages in the following cases, for example:
Neighbouring light grids must then be mounted at a large relative distance from one another so that they do not interfere with one another, i.e. the light from one light grid does not get into the other light grid.
The light from sources of interference, such as the sun or artificial radiation sources such as halogen lamps, lasers or LEDs, can easily reach the receivers. This can lead to malfunctions and faulty switching of the light grid.
Depending on the surface of objects in the vicinity of the light grid, a large minimum distance must be maintained between the beam axes of the light grid and these objects. The reason for this is that despite the actual interruption of the beam by the object to be detected, the transmitted light can receive light via reflections from surrounding objects and thus trigger a false switching.

In order to avoid these disadvantages and thus increase the performance of the light grid, the field of view of the light receivers of the light grid is usually restricted.

For this purpose, it is known that the receiving optics of light grids, which consist of one lens and one photodiode per light beam, are equipped with an aperture. The focal length of the lens and the diameter of the aperture, which is usually located at the focal point of the lens, then determine the reception angle (field of view) of the receiving optics.

This in turn has the disadvantage that the receiving optics take up a lot of space, typically between 10 mm and 20 mm, due to the required focal length of the lens and the thickness of the lens. In addition to the lens, a so called tube is always required to integrate the aperture and in particular to block unwanted light. Due to the number of these components of a receiving optic and the requirement of exact positioning of the components relative to each other, production is complex and correspondingly cost-intensive.

On the basis of this state of the art, it is the object of the invention to provide an improved light grid which can avoid the aforementioned disadvantages.

This object is solved by a light grid with the features of claim 1.

The inventive light grid comprises:
several light emitting units for emitting emitted light beams,
several light receiving units, which deliver reception signals according to the incidence of light and which can receive the emitted light beams to form the light grid in case of free beam paths,
at least a receiving optic,
an evaluation unit having electronic components to evaluate the intensity of the incidence of light on the light receiving units.

According to the inventive subject matter, the receiving optic comprises a substrate having a microlens array, each microlens having an aperture associated therewith, the apertures on the substrate each being at the focal point of the associated microlens for restricting a field of view of the light receiving units.

The structure formed in this way effectively restricts the field of view of the assigned light receiving unit (i.e. receiving angle), while at the same time effectively saving installation space due to the short focal lengths of microlenses on the one hand and, on the other hand, the area on which light detectable by the light receiving unit, can impinge is not smaller than in known light grids. On the contrary, this area can even be increased without changing the construction depth. In conventional light grids, the receiving area is determined by the size of the receiving lens and the photodiode can be small. According to the invention this principle is reversed, because now the receiving surface is determined by the size of the photodiode. In the inventive design an exact assignment between a single light receiving unit (photodiode) and certain receiving optics is not necessary and therefore not intended.

Each pair of microlens and associated aperture alone act as an element that restricts the reception angle. Depending on the size of the photosensitive surface of a light receiving unit, a certain number of microlenses are “assigned” to the light receiving unit, i.e. those that lie above the photosensitive surface. This is a further advantage. It is not necessary to align optical receiver with a light-receiving element according to the inventive subject matter.

By varying the microlens geometry, microlens thickness, aperture diameter and material thickness of the aperture, the receiving angle can be adjusted and optical crosstalk between adjacent channels can be minimized. Light from the field of view is received and effectively suppressed outside the field of view.

In addition, the microstructured substrate can be designed very thin and thus very space-saving, for example as a film.

Furthermore, the production of light grids according to the inventive subject matter is considerably simplified. Instead of having to join several components, i.e. lens and tube as well as the electronic card containing the light receiving units (photodiodes) individually, only one element, the microstructured substrate, is applied in a simple way, preferably glued.

The light receiving units are advantageously designed as photodiode or avalanche photodiode (APD) or SPAD array (single photon avalanche diode). Each photodiode, APD or SPAD array contains a specific group of microlenses of the microlens array. The special advantage is that the horizontal alignment between the substrate with the micro lenses and the apertures on the one hand and the light receiving units on the other does not have to be exact. This tolerance simplifies production considerably. Alternatively, the light receiving units could also be designed as a common photodiode array.

In a preferred and simple way embodiment the substrate with the microlens array and the apertures are formed as a film. One piece of the microstructured film can only cover one light-receiving element at a time, so the film has several individual microlens arrays. Preferably, the microlens array of the film with the associated apertures is designed continuous, so that the film is assigned to all light receiving units. Thus the film can cover all photodiodes of a light grid or at least all photodiodes of a part of the light grid, if it is modular. With just a few assembly steps, the entire receiver optics are correctly mounted. Preferably, one microlens film strip per electronic card is used in order to realize pre-assemblies and to keep the temperature-induced expansion difference local. But in principle a film strip over the entire length of the light grid is also conceivable, then possibly with expansion joints in the film between the photodiodes to compensate for the temperature-induced expansion difference between the film and the carrier.

In particularly advantageous embodiment the apertures containing surface of the substrate is adhesively. The microstructured substrate can thus easily be bonded to the photodiodes, to a shielding plate or to another element in front of the photodiodes. Alternatively, the substrate could also be glued to the outer surface of a front window of a housing. In another alternative, the microlens side is made adhesive and the film is applied to the inside of the front window.

Advantageously, the microlenses of a microlens array border each other without gaps in order to maximize the transmission of the substrate. Without gaps, all light minus transmission losses from the field of view is projected onto the aperture openings and thus onto the receiver unit.

In a further embodiment, such microlenses, which are adjacent to each other without gaps, are hexagonal in shape.

For cost-effective production, it is advantageous to produce the microlens array in an embossing process.

A particularly simple and thus cost-effective production for the apertures is given, if the apertures are formed from a light-tight coating with apertures. Such a coating can be produced efficiently by known coating processes, e.g. painting, etching, lithography or the like. Alternatively, the aperture layer consists of metal.

The aperture openings themselves can be not only round but also elliptical, square or rectangular in shape, if an elliptical, square or rectangular field of view is to be realised instead of a round one.

In a further embodiment, the substrate has an edge contour. By means of this edge contour, the substrate can be fixed relative to the photodiodes using, for example, locating pins.

In a further embodiment, the substrate has a spectral filter, which is then spectrally matched to the emitted light, so that further suppression of extraneous light can be achieved.

In a further embodiment, the substrate has a polarization-effective function, which can also be advantageously used to suppress extraneous light.

The film or substrate with the microlenses can also have different areas with different combinations of microlenses and apertures, for example to easily realize different viewing areas of the light grid. These areas can, for example, be arranged like chess boards on the film.

In the following, the invention will be explained in detail with reference to the drawing using exemplary embodiments. In the drawing:

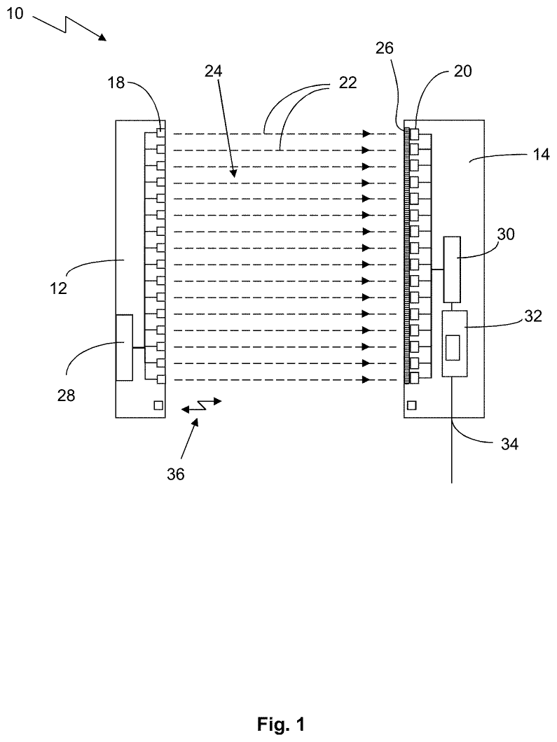

FIG. 1 shows a schematic representation of a light grid according to the inventive subject matter;

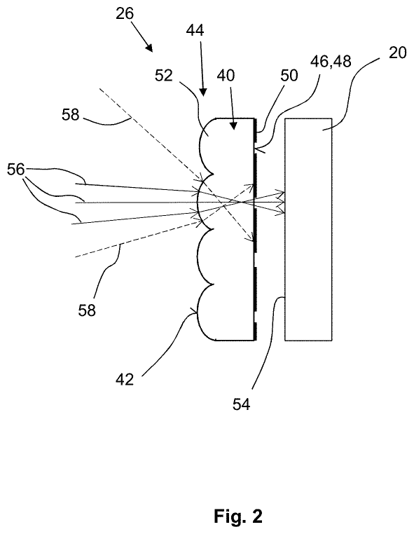

FIG. 2 shows a schematic representation of one or part of a receiving optic and light receiving unit;

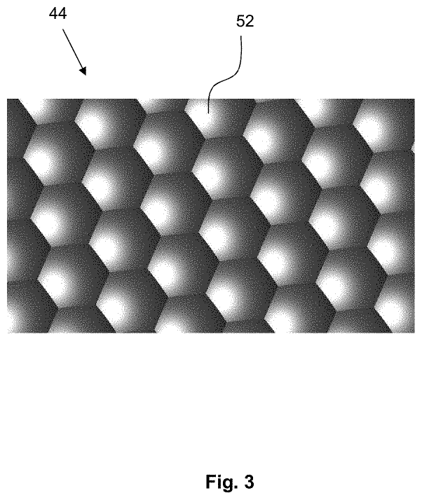

FIG. 3 shows a schematic representation of a top view of a microlens array.

A light grid 10 in accordance with the inventive subject matter comprises a transmitter housing 12 and a receiver housing 14. The transmitter housing 12 has a row of light emitting units 18 arranged in a longitudinal direction (hereinafter also called y-direction). The receiver housing 14 has a row of light receiving units 20 arranged also in y-direction. Each light emitting unit 18 is assigned to an opposite receiving unit 20, so that between transmitter-receiver pairs in each case there are light beams which are symbolized as arrows 22. Each light emitting unit 18 preferably comprises an emitting optic which forms the emitted light beams 22. The light receiving units 20 are preceded by a receiving optic 26 in order to direct light onto the light receivers 20, as shown in detail below.

The light beams 22 as a whole define a surveillance area 24, which is monitored to determine whether one or more of the light beams 22 are completely or partially interrupted by an object not shown in the drawing. Such an interruption is detected in an evaluation unit 32, which evaluates the reception signals of all light receiving units 20 after amplification 30, and a corresponding signal is output at an output 32. The output signal can be a simple switching signal (“object in protective field yes/no”) or a signal with more information, e.g. where the object is located. On the transmitter side, control electronics 28 are provided for controlling the light transmitters 18.

The transmitter units 18 and the light receiving units 20 in their row have a usually even distance A to each other, which is also called grid dimension. For special applications it can also be useful to have an irregular grid. Each light emitting unit has a light receiving unit opposite to it. The assignment of an activated light emitting unit 18 to an activated light receiving unit is carried out by the control unit 28 and the evaluation unit 32, which are synchronised with each other and can exchange synchronisation signals via a communication link 36.

If exactly opposite positioned transmitters/receivers are activated at the same time, the surveillance area consists of the beam bundles 22 shown schematically in FIG. 1. As is well known, not all transmitters 18 are typically activated at the same time, but the transmitters 18 and corresponding receivers 20 are switched (activated) cyclically and individually in rapid succession, so that only one transmitter-receiver pair and thus one beam is activated at a time. The cycle frequency (clock frequency) is very high, so that objects that move or are conveyed through the surveillance area 24 are quasi-stationary.

The invention now refers to the receiving optic 26. The receiving optic 26 serves to direct light onto the light receiving units 20, the light coming from a certain direction, namely from the direction in which the associated light emitting unit 18 is located. So the “correct” light beam 22 and nothing else should be received.

The receiving optic 26 of the inventive subject matter, which is shown in more detail but still schematically in FIG. 2, now comprises a substrate 40, on one side 42 of which, namely the side facing the light rays, a microlens array 44 is formed and on the opposite side facing the light receiving unit 46 apertures 50 are formed, whereby for each microlens 52 one of the apertures 50 is assigned. The apertures 50 lie ideally in the focal point of the assigned microlens 52. The term “at the focal point” should therefore mean that the aperture is preferably at the focal point of a microlens or at least close by if there are tolerances.

The microlenses can be encapsulated with a transparent protective layer for mechanical protection. The refractive index of the protective layer should be as small as possible. The lens contour must be adjusted according to the refractive indices so that the apertures remain at the focal point of the system. The apertures themselves do not necessarily have to be provided on a surface, but the apertures can also be provided in the structure or a protective layer can also be provided on the apertures side.

The structure 40 formed in this way restricts the field of view, i.e. the reception angle Ω of the assigned light receiving unit 20 is restricted to a value defined by the microlenses 52 and the aperture opening. Only the light rays 56 within this angle Ω reach the light receiving unit. All light passing through the aperture is incident on the light-receiving unit 20 behind it, which is located immediately behind or at least at a small distance from the apertures 50. Those microlenses 52 that cover a light receiving surface 54 of a light receiving unit 20 define the light receiving surface and direct the light onto the light receiving unit 20. If the light receiving units 20 are spaced apart and the microstructured substrate 40 is continuous, then the light receiving surface is always defined only by the microlenses 52 that are in front of a light receiver 20. The microlenses that sit “in between” are inactive. This is one of the great advantages of the invention. This is because there is no need to assign receiving optics to light receivers, but only to ensure that the structure covers the light receivers.

Each pair of microlens 52 and associated aperture 50 acts as a receiving angle-restricting element. By varying the microlens geometry, microlens thickness, aperture diameter and material thickness of the aperture, the reception angle Ω can be adjusted. FIG. 2 shows an example of two light beams 58 outside the reception angle Ω as dashed lines. Optical crosstalk between adjacent channels can be minimized.

In an advantageous way, the light receiving units 20 are each designed as photodiodes. Thus, a large number of microlenses 52 is assigned to a photodiode.

The light receiving units could also be designed as avalanche photodiode (APD) or SPAD array (single-photon avalanche diode). Each photodiode, APD or SPAD array contains a certain group of microlenses of the microlens array, which direct the light from the receiving angle onto the light receiver.

Alternatively, the light receiving units could also be designed as a common photodiode linear array. Then it would make sense for the light emitting unit to emit a light line aligned in the direction of the photodiode line. The advantage would be the possibility of continuous monitoring of the surveillance area 24.

The microstructured substrate 40 can be very thin and thus very space-saving. In particular, the substrate 40 with the microlens array 44 and the apertures 50 is designed as a film. A piece of the microstructured film 60 can only cover one light-receiving element at a time, i.e. it has only one microlens array 44. However, it is preferable that—as indicated in FIG. 1—film 60 forms a continuous microlens array 44 and thus covers all photodiodes. Therefore, the film 60 is designed as an elongated strip and covers all photodiodes 20 of the light grid 10.

The film 60 with the apertures 50 is adhesive on the aperture side 46, so that it can be glued on the photodiodes 20, on a cover not shown in the drawing or on another element in front of the photodiodes 20.

FIG. 3 shows the top view of a section of one of the microlens arrays 44. Preferably, the microlenses 52 of the microlens array 44 adjoin each other without gaps in order to maximize the transmission of the substrate 40. Without gaps, all light except for transmission losses from the field of view is projected onto the aperture openings and thus onto the light receiving unit 20. In this preferred embodiment such gap-free adjacent microlenses 52 are hexagonal.

The individual microlenses 44 can be aspherical lenses, free-form lenses, Fresnel lenses or diffractive lenses.

Instead of a two-dimensional restriction of the field of view, a one-dimensional restriction of the receiving angle can be realized if the microlenses are designed as microcylinder lenses and the aperture openings are strip-shaped.

1. Light grid with
a plurality of light emitting units (18) for emitting light beams (22),
a plurality of light-receiving units (20) which can receive the emitted light beams (22) to form the light grid (10) in case the beam paths are free and which supply reception signals in accordance with the incidence of light,
of at least one receiving optic (26),
an evaluation unit (32) having electronic components for evaluating the intensity of the incidence of light on the light receiving units (20),
characterized in that
the receiving optics (26) comprise a substrate (40) having a microlens array (44),
wherein an aperture (50) is assigned to each microlens (52), respectively,
and the apertures (50) each lie in the focal point of the associated microlens (52) for restricting a field of view of the light-receiving units (20).

2. Light grid according to claim 1, characterized in that the light receiving units are each formed as a photodiode or avalanche photodiode (APD) or SPAD array (single-photon avalanche diode array), or the light receiving units are formed as a linear photodiode array.

3. Light grid according to one claim 1, characterized in that the substrate with the microlens array and the apertures is formed as a film.

4. Light grid according to claim 3, characterised in that the film with the microlens array with apertures covers a plurality, in particular all, of the light receiving units, i.e. is assigned to all.

5. Light grid according to one claim 1, characterized in that the microlenses are hexagonal in shape.

6. Light grid according to claim 1, characterized in that the microlens array is produced in an embossing process.

7. Light grid according to claim 1, characterized in that the apertures are formed from a opaque coating with aperture openings.

8. Light grid according to claim 7, characterized in that the aperture openings have an elliptical, square or rectangular shape.

9. Light grid according to claim 1, characterized in that the substrate is adhesively on its surface having the apertures.

10. Light grid according to claim 1, characterized in that the substrate has an edge contour for fixing.

11. Light grid according to claim 1, characterized in that the microlenses and/or the apertures are encapsulated with a transparent protective layer.

12. Light grating according to claim 1, characterized in that the substrate comprises a spectral filter.

13. Light grid according to claim 1, characterized in that the structure has a polarization-effective function.

14. Light grid according to claim 1, characterized in that the substrate with the microlenses has different areas, the areas having different microlens/aperture combinations.
